(19) United States
(12) Patent Application Publication
(10) Pub. No.: US 2006/0180836 A1
(43) Pub. Date: Aug. 17, 2006

(54) Semiconductor device and manufacturing method thereof

(75) Inventors: Hiroyasu Ishida, Gunma (JP); Makoto Oikawa, Gunma (JP); Kikuo Okada, Saitama (JP); Shouji Miyahara, Gunma (JP); Naohiro Ochiai, Gunma (JP); Kazunari Kushiyama, Gunma (JP)

Correspondence Address: MORRISON & FOERSTER LLP, 1650 TYSONS BOULEVARD, SUITE 300, MCLEAN, VA, 22102, US

(73) Assignee: SANYO ELECTRIC CO., LTD., Osaka (JP)

(21) Appl. No.: 11/355,196

(22) Filed: Feb. 16, 2006

(30) Foreign Application Priority Data
Feb. 16, 2005 (JP) 2005-039668

(51) Int. Cl. H01L 21/336; H01L 29/76; H01L 29/94

(52) U.S. Cl. 257/288; 438/286

(57) ABSTRACT

In the present invention, in a pattern in which gate electrodes are provided in a stripe shape and source regions are provided in a ladder shape, body regions are provided in a stripe shape parallel to the gate electrodes. A first body region is exposed to a surface of a channel layer between first source regions adjacent to the gate electrode, and a second body region is provided below a second source region which connects the first source regions to each other. Thus, avalanche resistance can be improved. Moreover, since a mask for forming the body region is no longer required, there is a margin in accuracy of alignment.

### BACKGROUND OF THE INVENTION

1. Field of the Invention

The present invention relates to a semiconductor device and a manufacturing method thereof, more particularly relates to a semiconductor device which prevents deterioration of avalanche resistance and a manufacturing method thereof.

2. Description of the Related Art

There has heretofore been known a semiconductor device having an insulated gate, in which a source region is formed into a ladder shape in a planar pattern. This technology is described for instance in Japanese Patent Application Publication No. Hei 11 (1999)-87702.

With reference to FIGS. 16 and 17, description will be given of a semiconductor device having a ladder-shaped source region as in the case of Patent Document 1, and a manufacturing method thereof. First, FIGS. 16A and 16B show, as an example, an n-channel trench MOSFET. FIG. 16B is a cross-sectional view along the line c-c in FIG. 16A.

A drain region 20 is provided by laminating an n− type epitaxial layer 22 on an n+ type silicon semiconductor substrate 21, and a p-type channel layer 24 is provided thereon. A trench 27 is provided so as to penetrate the channel layer 24 and reach the drain region 20. An inner wall of the trench 27 is covered with a gate oxide film 31, and a gate electrode 33 is provided, which is formed of polysilicon buried in the trench 27.

In a surface of the channel layer 24 adjacent to the trench 27, n+ type source regions 35 are provided. In the surface of the channel layer 24 between the source regions 35 of two adjacent cells, a p+ type body region 34 is provided. The gate electrode 33 is covered with an interlayer insulating film 36. On the source regions 35 and the body region 34, which are exposed to a contact hole CH between the interlayer insulating films 36, a source electrode 38 formed of aluminum alloy and the like is provided.

With reference to FIGS. 17A to 17C, description will be given of a method for manufacturing the MOSFET described above.

A drain region 20 is formed by laminating an n− type epitaxial layer 22 on an n+ type silicon semiconductor substrate 21, and a p-type channel layer 24 is formed on a surface of the drain region 20. A trench 27 is formed so as to penetrate the channel layer 24 and reach the drain region 20. A gate oxide film 31 is formed on an inner wall of the trench 27, and a gate electrode 33 is buried in the trench 27 (FIG. 17A).

Next, p-type impurities are selectively ion-implanted by use of a mask made of a photoresist film. Thereafter, n-type impurities are ion-implanted by use of a mask made of a new photoresist film PR. Subsequently, an insulating film is deposited on the entire surface by use of a CVD method and the like, and an n+ type source region 35 and a p+ type body region 34 are formed by reflow of the insulating film (FIG. 17B).

Furthermore, the interlayer insulating film 36 is etched by using a photoresist film (not shown) as a mask and is left at least on the gate electrode 33. At the same time, a contact hole CH with a source electrode 38 is formed. Thereafter, aluminum alloy and the like are sputtered on the entire surface to obtain a final structure shown in FIG. 17C.

In the pattern shown in FIG. 16A, the gate electrodes 33 are formed in a stripe shape and the source regions 35 are arranged into a ladder shape. The source regions 35 are formed of stripe-shaped source regions 35a along the gate electrodes 33 and source regions 35b which connect the source regions 35a. In FIG. 16A, for example, the source regions 35b extended in a horizontal direction come into contact with the source electrode 38. Meanwhile, the source regions 35a extended in a vertical direction come into contact with the source electrode 38 as shown in FIG. 16B. In the pattern in which the source regions 35 are formed into a ladder shape, source contact resistance can be reduced by securing a source contact area.

Moreover, the body region 34 is disposed to have an island shape in the surface of the channel layer 24 exposed from the source regions 35. Specifically, in the cross-sectional view along the line c-c, as shown in FIG. 16B, the body region 34 is provided in the surface of the channel layer 24. The body region 34 has an impurity concentration of about 1E19 to 1E20 cm⁻³. The channel layer 24 is a region having a relatively low impurity concentration. However, in the cross-sectional view along the line c-c, the body region 34 having a high impurity concentration is disposed below the contact hole CH. Specifically, a region having a relatively low impurity concentration does not actually exist immediately below the contact hole CH.

FIG. 18 shows a cross-sectional view along the line d-d in FIG. 16A. In the cross-sectional view along the line d-d, as shown in FIG. 18, the body region 34 is not disposed, but only the source region 35 is disposed in the surface of the channel layer 24.

In the case where the channel layer 24 is formed by ion implantation and diffusion of impurities, even a peak concentration is set to 1E17 cm⁻³. Specifically, in the pattern described above, the p-type channel layer 24 having a relatively low impurity concentration is disposed immediately below the n-type source region 35 having a high impurity concentration. Thus, a potential drop is caused by the low impurity concentration in the channel layer 24.

In the state described above, if a forward voltage is applied between the source region 35 and the channel layer 24 (between an emitter and a base) to cause a parasitic bipolar action, avalanche breakdown occurs.

As described above, in the pattern in which the source regions 35 are formed into a ladder shape, source contact resistance can be reduced by securing a source contact area. However, since the body region 34 is selectively provided, resistance immediately below the source region 35 is increased in the region where no body region 34 is provided. Thus, there is a problem that the parasitic bipolar action is likely to occur to deteriorate avalanche resistance.

### SUMMARY OF THE INVENTION

The present invention provides a semiconductor device that includes a drain region of a first general conductivity type, a channel layer disposed on the drain region and being of a second general conductivity type, an insulating film in contact with the channel layer, a plurality of stripe-shaped gate electrodes disposed on the drain region, each of the gate electrodes being in contact with the channel layer through the insulating film, a patterned source region of the first general conductivity type, the source region being on the channel layer and in contact with the insulating film, a plurality of first body regions disposed on the channel layer and being of the second general conductivity type, and a plurality of second body regions disposed on the channel layer and being of the second general conductivity type, wherein the second body regions are located deeper in a depth direction of the channel layer than the first body regions.

The present invention also provides a semiconductor device that includes a drain region of a first general conductivity type, a channel layer disposed on the drain region and being of a second general conductivity type, a plurality of stripe-shaped trenches penetrating the channel layer, a plurality of insulating films covering inner walls of corresponding trenches, a plurality of gate electrodes disposed in corresponding trenches, a patterned source region of the first general conductivity type, the source region being on the channel layer and in contact with the insulating film, a plurality of first body regions disposed on the channel layer and being of the second general conductivity type, and a plurality of second body regions disposed on the channel layer and being of the second general conductivity type, wherein the second body regions are located deeper in a depth direction of the channel layer than the first body regions.

The present invention provides a method of manufacturing a semiconductor device. The method includes providing a semiconductor substrate of a first general conductivity type, forming a semiconductor layer of the first general conductivity type on the substrate, forming a channel layer of a second general conductivity type on the semiconductor layer, forming an insulating film that is in contact with the channel layer, forming a plurality of stripe-shaped gate electrodes in contact with the insulating film, forming a source region of the first general conductivity type in a surface portion of the channel layer so as to be in contact with the insulating film, forming a plurality of first body regions of the second general conductivity type in the surface portion of the channel layer, and forming a plurality of second body regions of the second general conductivity type under the surface portion of the channel layer.

The present invention also provides a method of manufacturing a semiconductor device. The method includes providing a semiconductor substrate of a first general conductivity type, forming a semiconductor layer of the first general conductivity type on the substrate, forming a channel layer of a second general conductivity type on the semiconductor layer, forming a plurality of stripe-shaped trenches in the channel layer, forming an insulating film to cover inner walls of the trenches, forming a plurality of gate electrodes in corresponding trenches, forming a source region of the first general conductivity type in a surface portion of the channel layer so as to be in contact with the insulating film, forming a plurality of first body regions of the second general conductivity type in the surface portion of the channel layer, and forming a plurality of second body regions of the second general conductivity type under the surface portion of the channel layer.

### BRIEF DESCRIPTION OF THE DRAWINGS

FIG. 1A is a plan view and FIGS. 1B and 1C are cross-sectional views showing a semiconductor device of a first embodiment of the present invention.

FIG. 2 is a cross-sectional view showing a method for manufacturing a semiconductor device of the first embodiment of the present invention.

FIG. 3 is a cross-sectional view showing the method for manufacturing a semiconductor device of the first embodiment of the present invention.

FIG. 4 is a cross-sectional view showing the method for manufacturing a semiconductor device of the first embodiment of the present invention.

FIGS. 5A and 5B are cross-sectional views showing the method for manufacturing a semiconductor device of the first embodiment of the present invention.

FIGS. 6A and 6B are cross-sectional views showing the method for manufacturing a semiconductor device of the first embodiment of the present invention.

FIGS. 7A and 7B are cross-sectional views showing the method for manufacturing a semiconductor device of the first embodiment of the present invention.

FIGS. 8A and 8B are cross-sectional views showing the method for manufacturing a semiconductor device of the first embodiment of the present invention.

FIGS. 9A and 9B are cross-sectional views showing the method for manufacturing a semiconductor device of the first embodiment of the present invention.

FIGS. 10A and 10B are cross-sectional views showing the method for manufacturing a semiconductor device of the first embodiment of the present invention.

FIGS. 11A and 11B are cross-sectional views showing a semiconductor device of a second embodiment of the present invention.

FIGS. 12A and 12B are cross-sectional views showing a method for manufacturing a semiconductor device of the second embodiment of the present invention.

FIGS. 13A and 13B are cross-sectional views showing the method for manufacturing a semiconductor device of the second embodiment of the present invention.

FIGS. 14A and 14B are cross-sectional views showing the method for manufacturing a semiconductor device of the second embodiment of the present invention.

FIGS. 15A and 15B are cross-sectional views showing the method for manufacturing a semiconductor device of the second embodiment of the present invention.

FIG. 16A is a plan view and FIG. 16B is a cross-sectional view showing a conventional semiconductor device.

FIGS. 17A to 17C are cross-sectional views showing a method for manufacturing the conventional semiconductor device.

FIG. 18 is a cross-sectional view showing the conventional semiconductor device.

### DESCRIPTION OF THE PREFERRED EMBODIMENTS

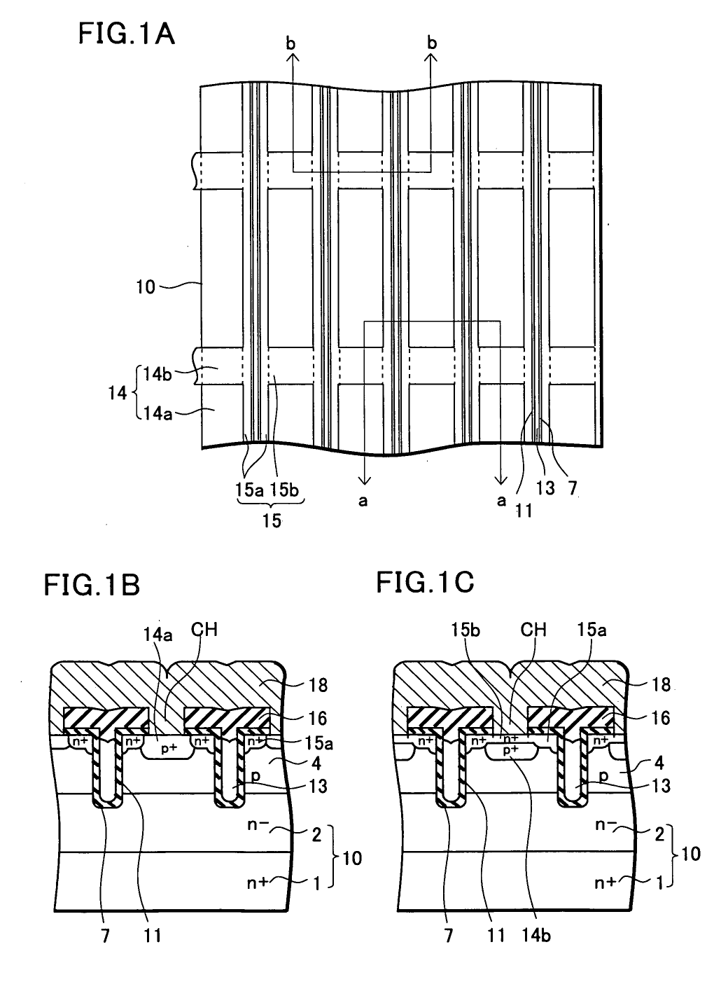

With reference to FIGS. 1 to 15, description will be given of embodiments of the present invention by taking an n-channel trench MOSFET as an example.

FIGS. 1A to 1C show a structure of a MOSFET of a first embodiment. FIG. 1A is a plan view, FIG. 1B is a cross-sectional view along the line a-a in FIG. 1A, and FIG. 1C is a cross-sectional view along the line b-b in FIG. 1A. Note that, in the plan view, an interlayer insulating film and a source electrode are omitted.

The MOSFET includes a semiconductor substrate 1, a semiconductor layer 2, trenches 7, a channel layer 4, gate electrodes 13, first source regions 15a, second source regions 15b, first body regions 14a and second body regions 14b.

As shown in FIG. 1A, the trenches 7 are provided in a substrate 10, and arranged in a stripe shape in a planar pattern. An inner wall of the trench 7 is covered with a gate oxide film 11, and the gate electrode 13 formed of polysilicon buried in the trench 7 is provided.

In a surface of the channel layer 4, a source region 15 that is a high-concentration n-type impurity region is provided. The source region 15 has the first and second source regions 15a and 15b. The first source regions 15a are provided in a stripe shape along the trenches 7 and the gate electrodes 13. Moreover, the second source region 15b is extended in a direction perpendicular to the first source regions 15a, and connects two of the first source regions 15a which are disposed on both sides of a body region 14. Furthermore, the second source regions 15b are disposed in a plurality of spots in the extending direction of the first source regions 15a. Specifically, the trenches 7 and the gate electrodes 13 have a stripe-shaped pattern, respectively, and the source regions 15 have a ladder-shaped pattern.

The body region 14 is a high-concentration p-type impurity region which is disposed parallel to the first source region 15a and the gate electrode 13. The body region 14 has the first and second body regions 14a and 14b. The first body region 14a is a region exposed to a surface of the substrate 10 in which the source region 15 is not disposed. Meanwhile, the second body region 14b is provided so as to overlap with the second source region 15b.

With reference to the cross-sectional views of FIGS. 1B and 1C, the substrate 10 to be a drain region is provided by laminating an n− type epitaxial layer 2 on an n+ type silicon semiconductor substrate 1. A p-type channel layer 4 is provided on the n− type epitaxial layer 2. The channel layer 4 is a p-type impurity layer provided on the epitaxial layer 2 by ion implantation and diffusion, for example. The trench 7 is provided so as to penetrate the channel layer 4 and reach the n− type epitaxial layer 2 (the drain region 10).

In the cross-sectional view along the line a-a, as shown in FIG. 1B, the first source regions 15a are provided in a surface of the channel layer 4 adjacent to the trench 7. Moreover, the first body region 14a is disposed in the surface of the channel layer 4 between the two adjacent first source regions 15a.

An interlayer insulating film 16 which covers the gate electrode 13 covers over the first source regions 15a. Specifically, in the cross-sectional view along the line a-a, a source electrode 18 provided on the surface comes into contact with only the first body region 14a through a contact hole CH between the interlayer insulating films 16.

Meanwhile, in the cross-sectional view along the line b-b, as shown in FIG. 1C, the second source region 15b connects two of the first source regions 15a adjacent to each other, and is exposed to the contact hole CH between the interlayer insulating films 16. The second body region 14b is disposed below the second source region 15b. The second body region 14b is buried in the channel layer 4 and is never exposed to the surface of the channel layer 4. As described later in detail, in the cross-sectional view along the line b-b, although impurities which form the second body region 14b also exist in the surface of the channel layer 4, the impurities are offset due to a high impurity concentration of the second source region 15b in the surface of the channel layer 4. Thus, the second body region 14b exists in a state of being buried in the channel layer 4 below the second source region 15b.

In the cross-sectional view described above, the source electrode 18 comes into contact with only the second source region 15b through the contact hole CH.

By forming the structure as described above, in the cross-sectional view along the line a-a, the first body region 14a is disposed in the surface of the channel layer 4. Moreover, in the cross-sectional view along the line b-b, the second body region 14b is disposed below the second source region 15b. Specifically, the p-type body region 14 having a high impurity concentration is disposed in the p-type channel layer 4 having a relatively low impurity concentration immediately below the n-type source region 15. Thus, it is possible to suppress occurrence of a voltage drop in the channel layer 4. Moreover, it is possible to avoid avalanche breakdown caused by a parasitic bipolar action.

Moreover, as described later, the body region 14 can be ion-implanted into the entire surface by using the interlayer insulating film 16 as a mask. Specifically, a mask for forming a body region, which has heretofore been required, is no longer required. Therefore, there is a margin in accuracy of alignment for one mask. It is possible to reduce of width of the margin and a cell density can be improved.

Moreover, the source regions 15 are formed in a ladder-shaped pattern, the second source region 15b comes into contact with the source electrode 18, and the first source region 15a never comes into contact therewith. Specifically, the first source region 15a becomes a resistor component, and a transistor structure including an emitter ballast resistor is realized. The parasitic bipolar action of the MOSFET or a bipolar transistor such as an IGBT (Insulated Gate Bipolar Transistor) has a positive temperature coefficient. Thus, if there is a slight increase in temperature due to a variation in bias applied to each cell in the MOSFET or the IGBT, secondary breakdown occurs.

In such a case, if an emitter ballast resistor having a negative temperature coefficient is connected to each cell, occurrence of the secondary breakdown can be prevented. Specifically, in this embodiment, even if the bias applied to each cell varies, temperature compensation is made possible by the first source region 15a. Thus, the secondary breakdown can be prevented.

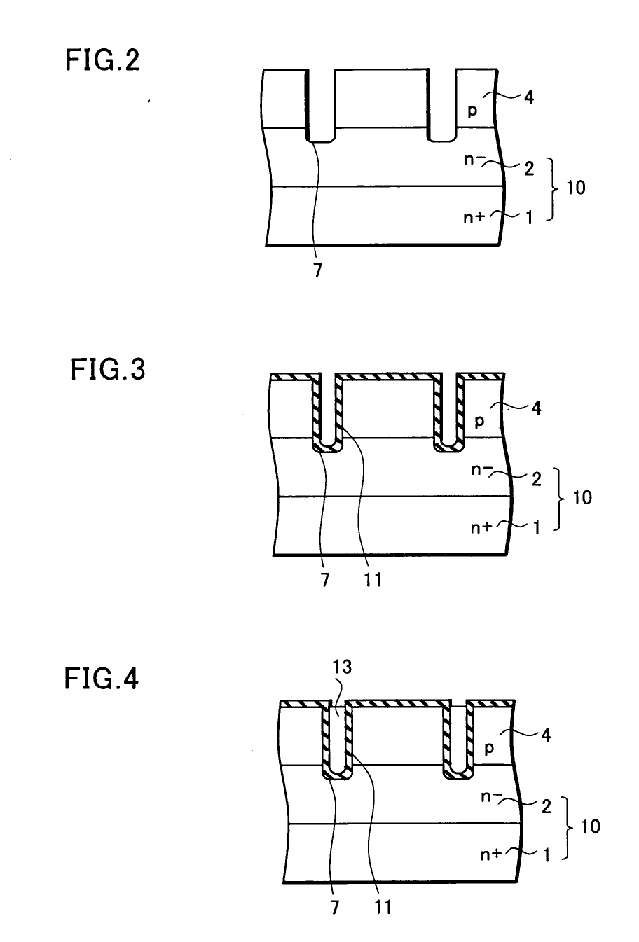

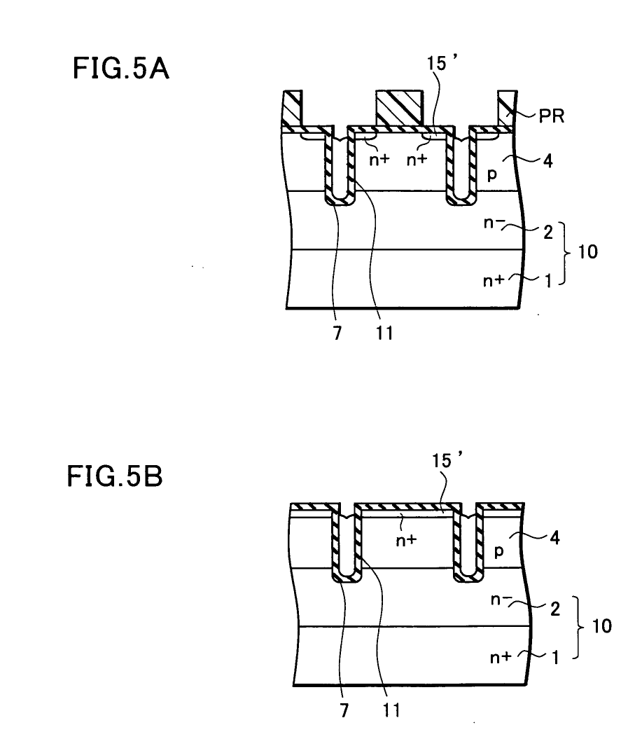

FIGS. 2 to 10 show a method for manufacturing the MOSFET described above. Note that, in the respective drawings, FIGS. 5A to 10A show cross-sectional views along the line a-a in FIG. 1A, and FIGS. 5B to 10B show cross-sectional views along the line b-b in FIG. 1A.

A method for manufacturing a semiconductor device of the first embodiment of the present invention includes the steps of: forming an opposite conductivity type channel layer on a drain region formed by laminating a one conductivity type semiconductor layer on a one conductivity type semiconductor substrate, and forming trenches in a stripe shape so as to penetrate the channel layer; forming an insulating film at least on an inner wall of each of the trenches; forming a gate electrode in the trench; forming a one conductivity type source region in a surface of the channel layer adjacent to the trench; and forming an opposite conductivity type first body region, which is positioned in the surface of the channel layer, and an opposite conductivity type second body region, which is buried in the channel layer.

First Step (see FIG. 2): forming an opposite conductivity type channel layer on a drain region formed by laminating a one conductivity type semiconductor layer on a one conductivity type semiconductor substrate, and forming trenches in a stripe shape so as to penetrate the channel layer.

First, a substrate 10 to be a drain region is prepared by laminating an n' type epitaxial layer 2 on an n+ type silicon semiconductor substrate 1. After an oxide film (not shown) is formed on a surface of the substrate 10, the oxide film in a formation region of a channel layer is etched. After boron (B), for example, is implanted by a dose of 1.0×10¹³ cm⁻² into the entire surface by using the oxide film as a mask, boron is diffused to form a p-type channel layer 4.

Next, trenches are formed. A CVD oxide film (not shown) which is made of NSG (non-doped silicate glass) is formed on the entire surface by use of a CVD method. Thereafter, a mask made of a photoresist film is provided except for portions to be trench openings. Subsequently, the CVD oxide film is partially removed by dry etching. Thus, the trench openings are formed, in which the n− type epitaxial layer 2 is exposed.

Furthermore, by use of the CVD oxide film as a mask, the silicon semiconductor substrate 10 in the trench openings is dry-etched by using CF and HBr gases. Thus, trenches 7 are formed. As a depth of the trench 7, a depth which penetrates the channel layer 4 is appropriately selected. As shown in FIG. 1A, the trenches 7 are formed in a stripe shape in a planar pattern.

Second Step (see FIG. 3): forming an insulating film at least on an inner wall of each of the trenches.

A dummy oxide film (not shown) is formed on inner walls of the trenches 7 and the surface of the channel layer 4 by dummy oxidation to eliminate etching damage in dry etching. Thereafter, the dummy oxide film formed by the dummy oxidation and the CVD oxide film used as a mask are simultaneously removed by use of an oxide film etchant such as hydrofluoric acid. Thus, a stable gate oxide film can be formed. Moreover, the openings of the trenches 7 are rounded by high-temperature thermal oxidation. Thus, there is also obtained an effect of avoiding electric field concentration in the openings of the trenches 7. Thereafter, a gate oxide film 11 is formed. Specifically, the entire surface is thermally oxidized (about 1000° C.) to form the gate oxide film 11 to have a thickness of, for example, about several hundred Å according to a threshold thereof.

Third Step (see FIG. 4): forming a gate electrode in the trench.

Furthermore, a non-doped polysilicon layer is deposited on the entire surface, and phosphorus (P), for example, is implanted at a high concentration and diffused to achieve a high conductivity. The polysilicon layer deposited on the entire surface is dry-etched without a mask to form a gate electrode 13 buried in the trench 7. Therefore the gate electrode 13 which have a stripe-shaped pattern is formed. Note that the gate electrode 13 may be buried in the trench 7 by depositing polysilicon doped with impurities on the entire surface and, thereafter, etching back the polysilicon.

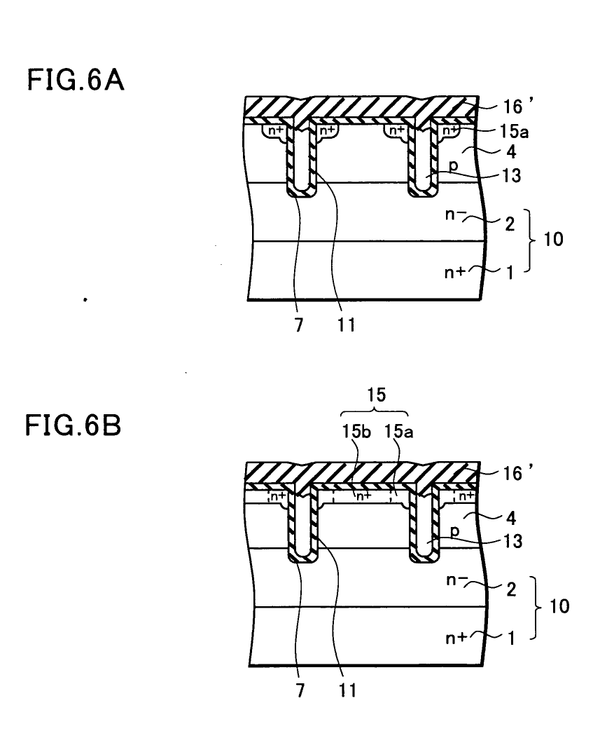

Fourth Step (see FIGS. 5 and 6): forming a one conductivity type source region in a surface of the channel layer adjacent to the trench.

A mask made of a photoresist film PR is provided, the photoresist film PR having a pattern in which ladder-shaped openings are provided in formation regions of source regions. Specifically, as shown in FIG. 5A, the photoresist film PR has openings selectively provided in formation regions of first source regions around the trenches 7 in the cross-sectional view along the line a-a in FIG. 1A. Moreover, as shown in FIG. 5B, the photoresist film PR has openings provided in formation regions of first and second source regions so as to expose the entire surface of the channel layer 4 between the adjacent trenches 7 in the cross-sectional view along the line b-b in FIG. 1A.

Thereafter, arsenic (As) which is an n-type impurity is ion-implanted by an acceleration energy of 100 keV and a dose of about 5×10¹⁵ cm⁻² to form an n+ type impurity region 15′.

Subsequently, as shown in FIGS. 6A and 6B, by use of a CVD method, an insulating film 16′ to be an interlayer insulating film is deposited on the entire surface. Specifically, the insulating film 16′ is made of a multilayer film such as BPSG (boron phosphorus silicate glass). By heat treatment (below 1000° C. for about 60 minutes) at the time of the film formation, the n+ type impurity region 15′ is diffused to form a first source region 15a and a second source region 15b. Therefore a source regions 15 which have a ladder-shaped pattern is formed.

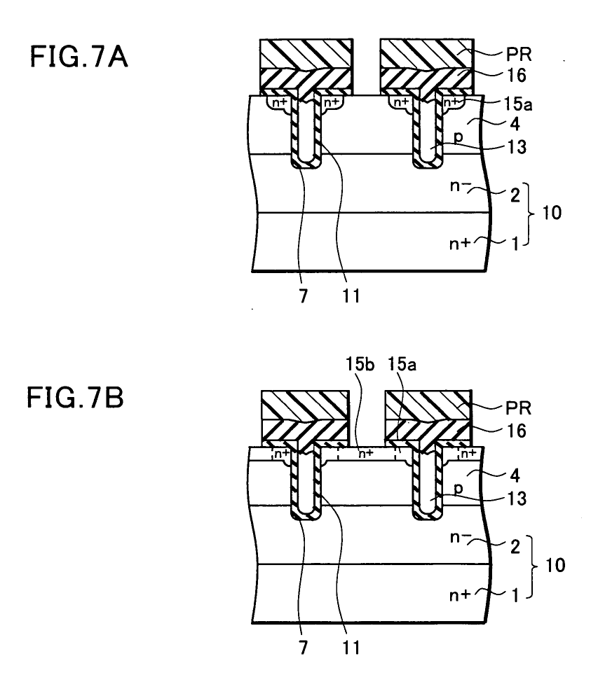

Fifth Step (see FIGS. 7 to 9): forming an opposite conductivity type first body region, which is positioned in the surface of the channel layer, and an opposite conductivity type second body region, which is buried in the channel layer.

As shown in FIGS. 7A and 7B, the insulating film 16′ is etched by using a new photoresist film PR as a mask, and interlayer insulating films 16 are left at least on the gate electrodes 13. At the same time, contact holes CH are formed, in which formation regions of body regions are exposed. Openings in the photoresist film PR, which are to be the formation regions of the body regions, are provided in a stripe-shaped pattern parallel to the gate electrodes 13 (the trenches 7). Thereafter, the photoresist film PR is removed.

The interlayer insulating films 16 are provided so as to completely cover the first source regions 15a, and only the second source region 15b is exposed between the interlayer insulating films 16.

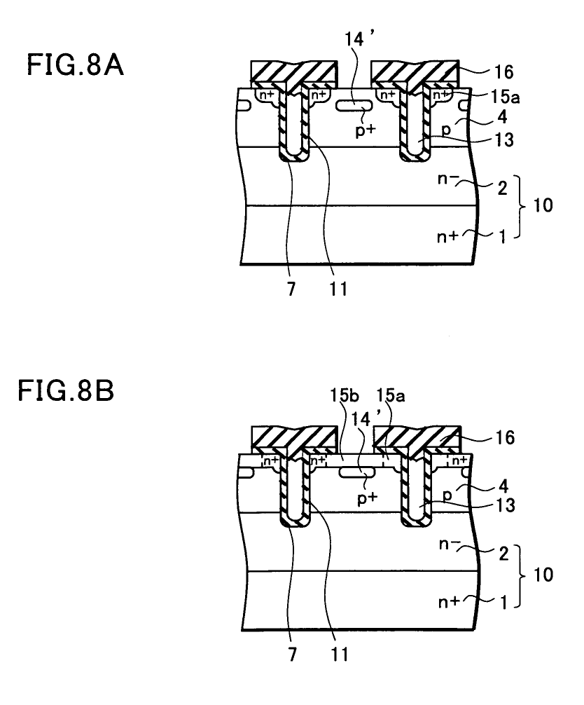

As shown in FIGS. 8A and 8B, p-type impurities are ion-implanted at a high acceleration by use of the interlayer insulating films 16 as a mask. That is, boron (B) or the like is ion-implanted by an acceleration energy of 100 keV or more and a dose of about the order of 1015 cm⁻² to form a p+ type impurity region 14′.

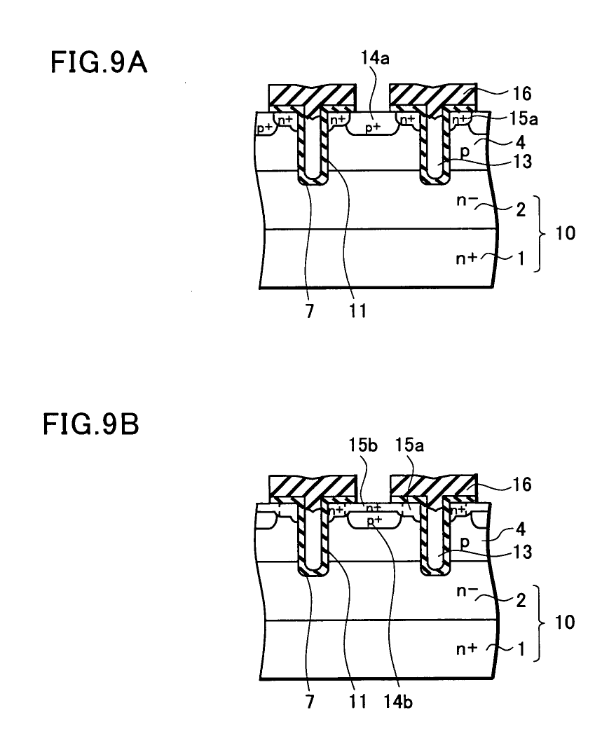

Subsequently, as shown in FIGS. 9A and 9B, heat treatment is performed at 900° C. for about 30 minutes to diffuse the p+ type impurity region 14′. Thus, a first body region 14a is formed, which is exposed to the surface of the channel layer 4 between the first source regions 15a. At the same time, a second body region 14b is formed, which is buried in the channel layer 4 below the second source region 15b. A body region 14(, the first body region 14a and the second body region 14b) stabilizes a substrate potential.

Here, the body region 14 is formed by high-acceleration ion implantation so as to position its peak at a depth of about 1 μm from the surface of the channel layer 4 (see FIGS. 8A and 8B). Thereafter, the body region 14 is diffused upward and downward by heat treatment, and the first body region 14a is exposed to the surface of the channel layer 4. Meanwhile, although the second body region 14b is similarly diffused, the high-concentration second source region 15b is disposed on the second body region 14b. Therefore, to be more specific, a part of the impurities forming the second body region 14b reaches the surface of the channel layer 4 but is offset by the second source region 15b. Thus, the second body region 14b is actually positioned in a state of being buried in the channel layer 4 below the second source region 15b.

Moreover, although the source region 15 is also further diffused by the heat treatment, since the source region 15 is formed of arsenic, a projected range distance Rp is short and a diffusion coefficient is low. Specifically, even if diffusion advances, a shallow diffusion layer is formed. Meanwhile, the body region 14 is formed by high-acceleration ion implantation of 100 keV or more, and the projected range distance Rp becomes longer than that of the impurities in the source region 15. Therefore, the second body region 14b can be positioned below the second source region 15b, as shown in FIG. 9B, by use of a difference in the projected range distance Rp.

As described above, the first body region 14a is provided in the surface of the channel layer 4, and the second body region 14b is provided in the channel layer 4 immediately below the second source region 15b.

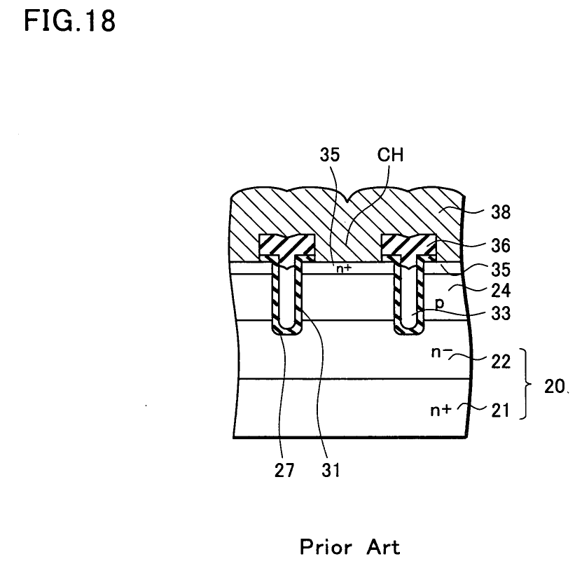

If the body region 34 is selectively formed between the ladder-shaped source regions 35 as in the case of the conventional case, the channel layer 24 which is a p-type low-concentration impurity region is disposed below the source region 35 where no body region 34 is disposed. Thus, a potential drop occurs (see FIG. 18).

However, in this embodiment, the second body region 14b is disposed below the second source region 15b. Therefore, a relatively low-concentration region no longer actually exists in the channel layer 4. Thus, it is possible to prevent avalanche breakdown caused by the potential drop.

Moreover, masks have heretofore been required to form the source regions, the body regions and the interlayer insulating films, respectively. Thus, it has been required to consider misalignment of three masks. However, according to this embodiment, the interlayer insulating films 16 can be used as the mask for forming the body regions 14. Therefore, the mask for forming the body regions 14 is no longer required, and there is a margin in accuracy of alignment for one mask.

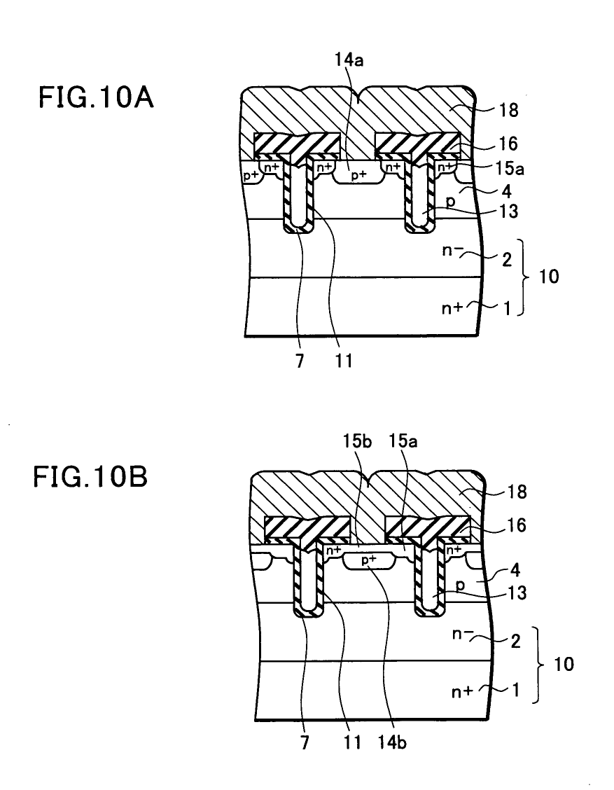

Sixth Step (see FIGS. 10A and 10B): forming a source electrode on the entire surface.

In order to suppress silicon nodules and prevent spike (mutual diffusion between metal and a silicon substrate), a barrier metal layer (not shown) is formed by use of a titanium material.

Thereafter, metal layer, for example aluminum alloy, is sputtered to have a film thickness of about 5000 Å on the entire surface. Subsequently, in order to stabilize the metal layer and the surface of the silicon substrate 10, alloying heat treatment is performed. This heat treatment is performed for about 30 minutes at 300 to 500° C. (for example, about 400° C.) in hydrogen-containing gas. Thus, crystal distortion in the metal film is removed to stabilize an interface.

The metal layer is patterned into a desired shape, and, although not shown in the drawings, SiN or the like to be a passivation film is provided. Thereafter, in order to eliminate damage, heat treatment is further performed for about 30 minutes at 300 to 500° C. (for example, 400° C.).

Thus, a source electrode 18 is formed, which comes into contact with the first body region 14a and the second source region 15b, respectively, which are exposed from the contact hole CH. Specifically, the body region 14 comes into contact with the source electrode 18 in the first body region 14a (FIG. 10A), and the source region 15 comes into contact with the source electrode 18 in the second source region 15b (FIG. 10B).

Moreover, as shown in FIG. 10B, the second body region 14b is provided immediately below the second source region 15b which comes into contact with the source electrode 18. Therefore, in the vicinity of the surface of the channel layer 4, the second body region 14b is formed in the region having a relatively low impurity concentration. Thus, no potential drop is caused by a difference in the impurity concentration, and avalanche breakdown can be prevented.

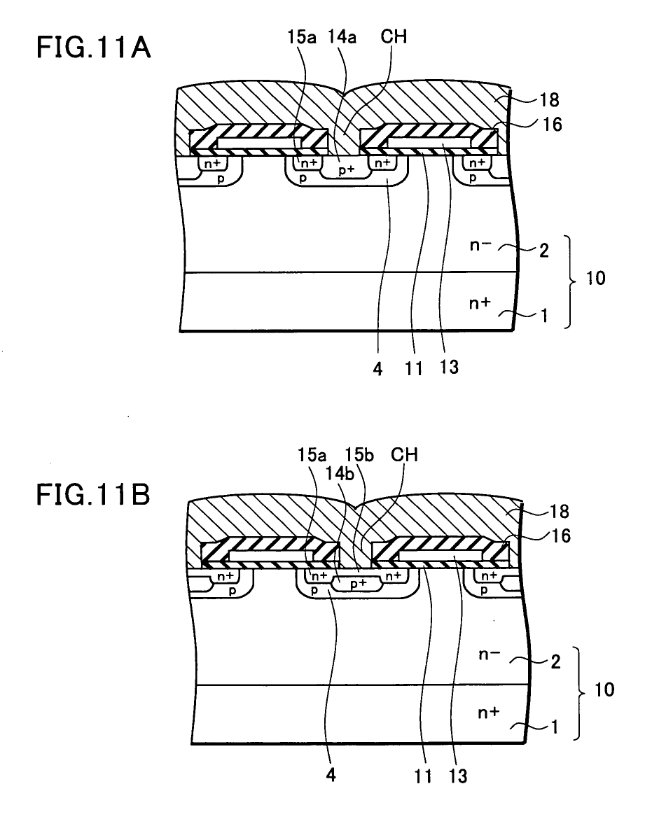

With reference to FIGS. 11 to 15, a second embodiment of the present invention will be described. The second embodiment is the case of a planar MOSFET.

FIGS. 11A and 11B are cross-sectional views of the planar MOSFET. Note that a plan view of the second embodiment is the same as FIG. 1A, FIG. 11A is a cross-sectional view along the line a-a in FIG. 1A, and FIG. 11B is a cross-sectional view along the line b-b in FIG. 1A. Note that a patterning width of gate electrodes 13 is wider than that shown in FIG. 1A.

A surface of a channel layer 4 is covered with a gate oxide film 11, and the gate electrodes 13 made of polysilicon are provided on the gate oxide film 11. The gate electrodes 13 are formed in a stripe-shaped pattern in a planar pattern as shown in FIG. 1A.

At positions adjacent to the gate electrodes 13 in the surface of the channel layer 4, source regions 15 are provided, which are high-concentration n-type impurity regions. Each of the source regions 15 has a first source region 15a and a second source region 15b (FIG. 11B). A body region 14 is a high-concentration p-type impurity region which is disposed parallel to the first source region 15a and the gate electrode 13. The body region 14 has a first body region 14a provided in the surface of the channel layer 4 and a second body region 14b buried in the channel layer 4. The first and second source regions 15a and 15b and the first and second body regions 14a and 14b have the same patterns as those of the first embodiment. Thus, detailed description thereof will be omitted (see FIG. 1A).

Specifically, in the region corresponding to the cross section along the line a-a in FIG. 1A, the first source regions 15a are provided in the surface of the channel layer 4 adjacent to the gate electrodes 13 as shown in FIG. 11A. The first body region 14a is disposed in the surface of the channel layer 4 between the two adjacent first source regions 15a, and is exposed to the surface of the channel layer 4.

An interlayer insulating film 16 which covers the gate electrode 13 covers over the first source regions 15a. Specifically, in the cross-sectional view along the line a-a in FIG. 1A, a source electrode 18 provided on the surface comes into contact with only the first body region 14a through a contact hole CH between the interlayer insulating films 16 (FIG. 11A).

Meanwhile, in the cross-sectional view along the line b-b in FIG. 1A, as shown in FIG. 11B, the second source region 15b connects the two adjacent first source regions 15a and is exposed to the contact hole CH between the interlayer insulating films 16. The second body region 14b is disposed below the second source region 15b. The second body region 14b is buried in the channel layer 4 and is never exposed to the surface of the channel layer 4. Specifically, in the cross-sectional view along the line b-b in FIG. 1A, the source electrode 18 comes into contact with only the second source region 15b through the contact hole CH.

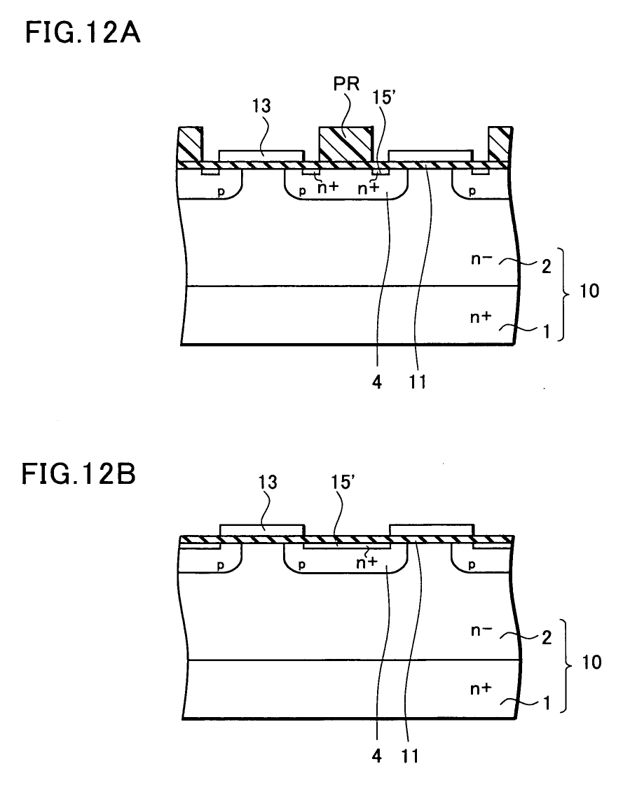

With reference to FIGS. 12 to 15, description will be given of a method for manufacturing the MOSFET of the second embodiment. Note that, in the respective drawings, FIGS. 12A to 15A show cross-sectional views along the line a-a in FIG. 1A, and FIGS. 12B to 15B show cross-sectional views along the line b-b in FIG. 1A. Moreover, for the description that overlaps between the first and second embodiments, detailed description thereof will be omitted.

First to Fourth Steps: first, with reference to FIGS. 12A and 12B, a substrate 10 to be a drain region is prepared by laminating an n− type epitaxial layer 2 on an n+ type silicon semiconductor substrate 1. On a surface of the substrate 10, a p-type channel layer 4 is formed. The entire surface is thermally oxidized to form a gate oxide film 11 on a surface of the channel layer 4, the gate oxide film having a film thickness according to a threshold. A polysilicon layer is deposited on the entire surface, a mask is provided, and etching is performed. Thus, gate electrodes 13 are formed in a stripe-shaped pattern in the planar pattern. The gate electrodes 13 come into contact with the channel layer 4 with the gate oxide film 11 interposed therebetween.

A mask in which formation regions of source regions are patterned into a ladder shape is provided by use of a photoresist film PR. Specifically, as shown in FIG. 12A, the photoresist film PR has openings selectively provided in formation regions of first source regions around the gate electrodes 13 in the cross-sectional view along the line a-a in FIG. 1A. Moreover, as shown in FIG. 12B, the photoresist film PR has openings provided in formation regions of first and second source regions so as to expose the surface of the channel layer 4 between the adjacent gate electrodes 13 in the cross-sectional view along the line b-b in FIG. 1A.

Thereafter, as an n-type impurity, arsenic is ion-implanted by an acceleration energy of 100 keV and a dose of about 5×10¹⁵ cm⁻² to form an n+ type impurity region 15′.

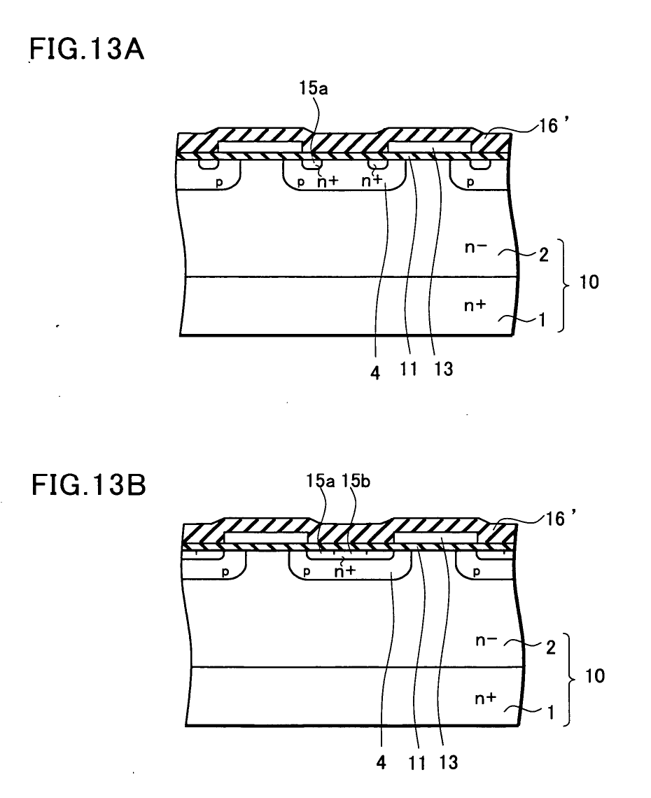

With reference to FIGS. 13A and 13B, by use of a CVD method, an insulating film 16′, such as BPSG (boron phosphorus silicate glass), to be an interlayer insulating film is deposited on the entire surface. By heat treatment (below 1000° C. for about 60 minutes) at the time of the film formation, the n+ type impurity region 15′ is diffused to form a first source region 15a and a second source region 15b.

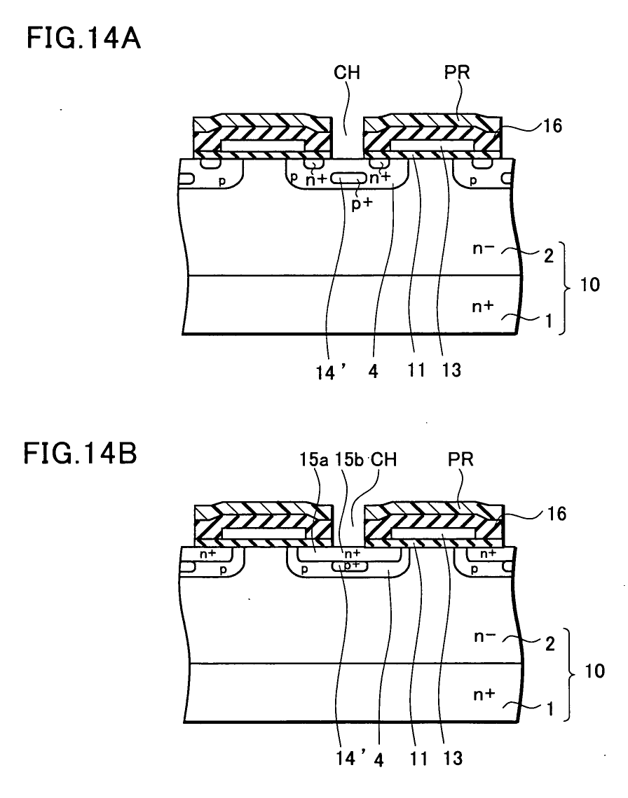

Fifth Step: as shown in FIGS. 14A and 14B, the insulating film 16′ is etched by using a new photoresist film PR as a mask, and interlayer insulating films 16 which cover at least the gate electrodes 13 are left. At the same time, contact holes CH are formed, in which formation regions of body regions are exposed. Openings in the mask, which are to be the formation regions of the body regions, are provided in a stripe-shaped pattern parallel to the gate electrodes 13.

By use of the interlayer insulating films 16 as a mask, p-type impurities are ion-implanted at a high acceleration. The ion implantation is performed by an acceleration energy of 100 keV or more and a dose of about the order of 1015 cm⁻² to form a p+ type impurity region 14′.

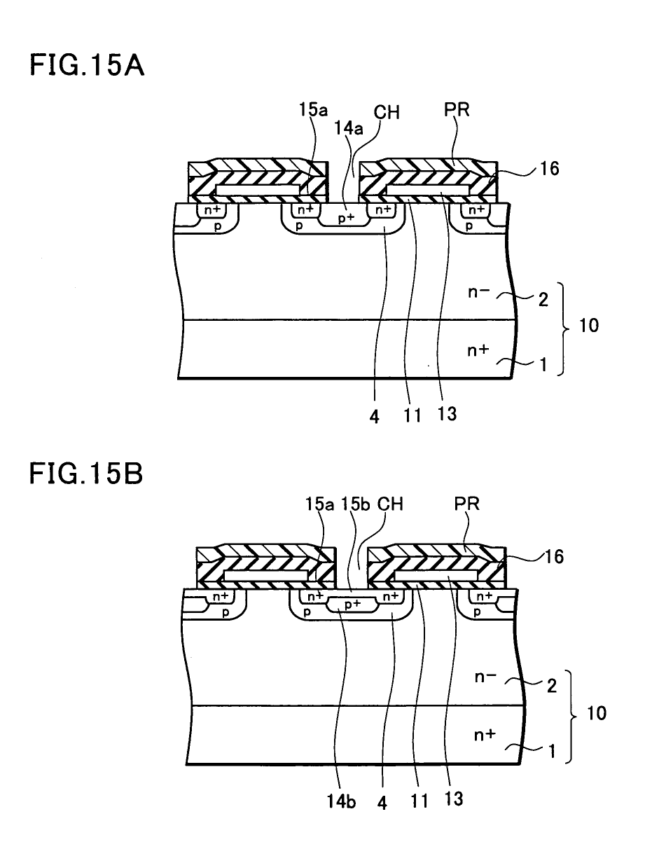

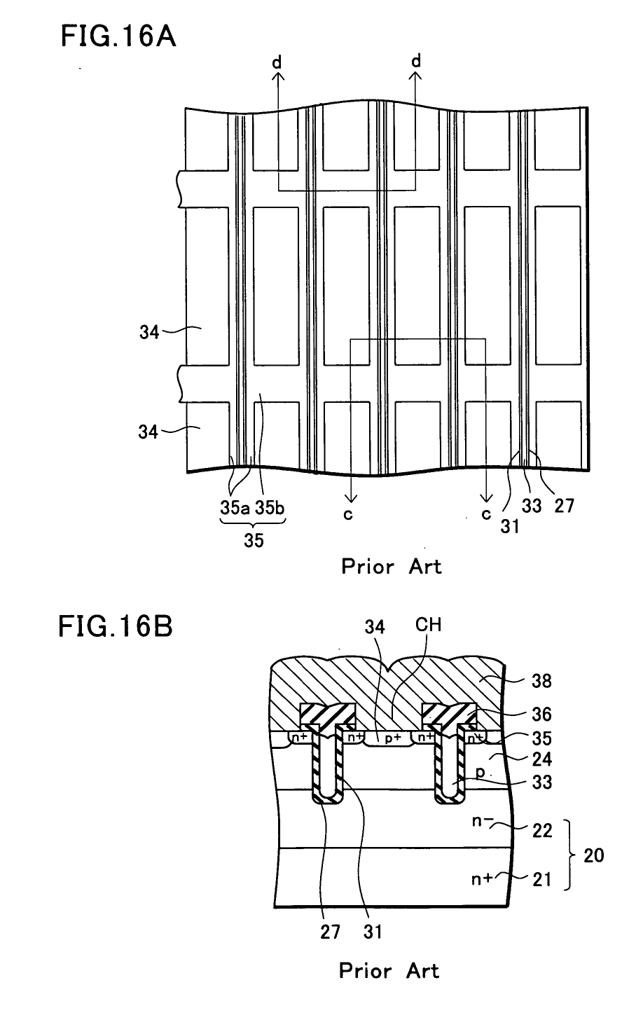

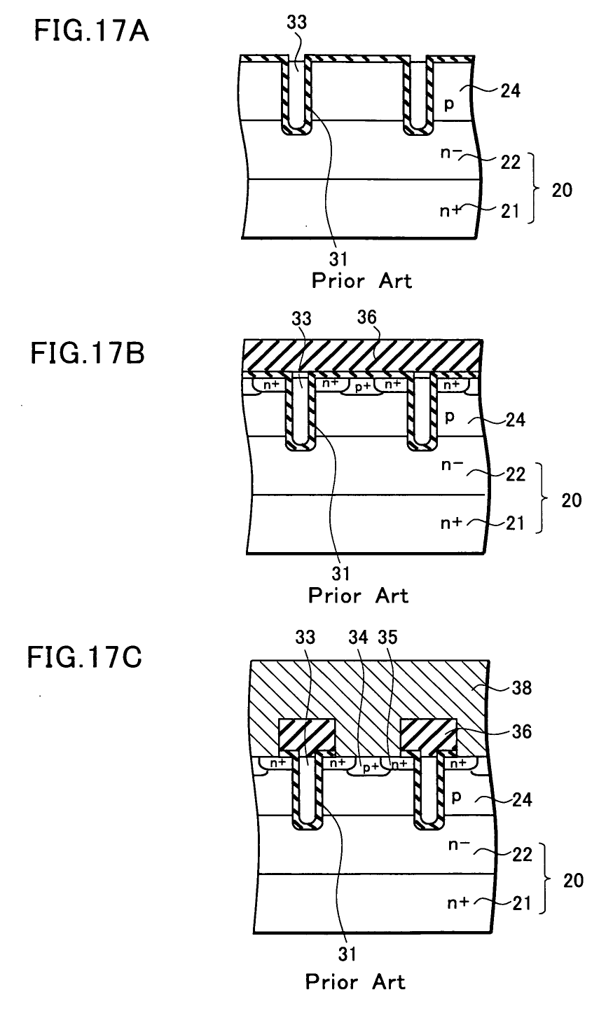

Thereafter, as shown in FIGS. 15A and 15B, heat treatment is performed at 900° C. for about 30 minutes to diffuse the p+ type impurity region 14′. Thus, a first body region 14a is formed, which is exposed to the surface of the channel layer 4 between the first source regions 15a. At the same time, a second body region 14b is formed, which is buried in the channel layer 4 below the second source region 15b. A body region 14 (the first body region 14a and the second body region 14b) stabilizes a substrate potential.

Subsequently, a barrier metal layer (not shown) is formed on the entire surface, and aluminum alloy is sputtered to have a film thickness of about 5000 Å. Thereafter, alloying heat treatment is performed to form a source electrode 18 patterned into a desired shape. Thus, a final structure shown in FIGS. 11A and 11B is obtained.

The embodiments of the present invention have been described above by taking the n-channel MOSFET as an example. However, the embodiments of the present invention are similarly applicable to a p-channel MOSFET having a conductivity type reversed. Moreover, without being limited thereto, the embodiments of the present invention are similarly applicable to insulated gate semiconductor elements including an IGBT that is a bipolar transistor in which an opposite conductivity type semiconductor layer is disposed below a one conductivity type silicon semiconductor substrate 1. Accordingly, similar effects can be obtained.

According to the embodiments of the present invention, first, in a structure having a source contact area improved by forming gate electrodes in a stripe-shaped pattern and providing source regions in a ladder-shaped pattern, body regions are formed in a stripe-shaped pattern and are disposed immediately below the source regions. Therefore, there is no longer a region partially susceptible to avalanche breakdown. Thus, as a whole device, avalanche resistance is improved.

Moreover, since the source regions are formed in a ladder-shaped pattern, first source regions along the gate electrodes can be used as emitter ballast resistors. Thus, in the MOSFET, it is possible to prevent secondary breakdown caused by a parasitic bipolar action. Moreover, the secondary breakdown can also be prevented in the case of an IGBT which is a bipolar transistor.

Secondly, the body regions can be formed by ion implantation using an interlayer insulating film as a mask. Thus, a mask for forming the body regions can be reduced. Consequently, there is a margin in accuracy of alignment for one mask. It is possible to reduce of width of the margin and a cell density can be improved.

What is claimed is:

1. A semiconductor device comprising:
a drain region of a first general conductivity type;
a channel layer disposed on the drain region and being of a second general conductivity type;
an insulating film in contact with the channel layer;
a plurality of stripe-shaped gate electrodes disposed on the drain region, each of the gate electrodes being in contact with the channel layer through the insulating film;
a patterned source region of the first general conductivity type, the source region being on the channel layer and in contact with the insulating film;
a plurality of first body regions disposed on the channel layer and being of the second general conductivity type; and
a plurality of second body regions disposed under a source region and being of the second general conductivity type,

2. A semiconductor device comprising:
a drain region of a first general conductivity type;
a channel layer disposed on the drain region and being of a second general conductivity type;
a plurality of stripe-shaped trenches penetrating the channel layer;
a plurality of insulating films covering inner walls of corresponding trenches;
a plurality of gate electrodes disposed in corresponding trenches;
a patterned source region of the first general conductivity type, the source region being on the channel layer and in contact with the insulating film;
a plurality of first body regions disposed on the channel layer and being of the second general conductivity type; and
a plurality of second body regions disposed under the patterned source region and being of the second general conductivity type,

3. The semiconductor device of claim 1 or 2, wherein the patterned source region is patterned so as to include a plurality of stripe regions parallel to the gate electrodes and a plurality connecting regions connecting the stripe regions, the first body regions are disposed between corresponding stripe regions of the source region, and the second body regions are disposed under corresponding connecting regions of the source region.

4. The semiconductor device of claim 1 or 2, further comprising a source electrode in direct contact with the first body regions.

5. The semiconductor device of claim 3, further comprising a source electrode in direct contact with the connecting regions of the source region.

6. The semiconductor device of claim 1 or 2, wherein the first and second body regions are disposed parallel to the gate electrodes.

7. A method of manufacturing a semiconductor device, comprising:
providing a semiconductor substrate of a first general conductivity type;
forming a semiconductor layer of the first general conductivity type on the substrate;
forming a channel layer of a second general conductivity type on the semiconductor layer;
forming an insulating film that is in contact with the channel layer;
forming a plurality of stripe-shaped gate electrodes in contact with the insulating film;
forming a source region of the first general conductivity type in a surface portion of the channel layer so as to be in contact with the insulating film;
forming a plurality of first body regions of the second general conductivity type in the surface portion of the channel layer; and
forming a plurality of second body regions of the second general conductivity type under the surface portion of the channel layer.

8. A method of manufacturing a semiconductor device, comprising:
providing a semiconductor substrate of a first general conductivity type;
forming a semiconductor layer of the first general conductivity type on the substrate;
forming a channel layer of a second general conductivity type on the semiconductor layer;
forming a plurality of stripe-shaped trenches in the channel layer forming an insulating film to cover inner walls of the trenches;
forming a plurality of gate electrodes in corresponding trenches;
forming a source region of the first general conductivity type in a surface portion of the channel layer so as to be in contact with the insulating film;
forming a plurality of first body regions of the second general conductivity type in the surface portion of the channel layer; and
forming a plurality of second body regions of the second general conductivity type under the surface portion of the channel layer.

9. The method of claim 7 or 8, wherein the source region is patterned so as to include a plurality of stripe regions parallel to the gate electrodes and a plurality connecting regions connecting the stripe regions, the first body regions are formed between corresponding stripe regions of the source region, and the second body regions are formed under corresponding connecting regions of the source region.

10. The method of claim 7 or 8, further comprising forming an interlayer insulating film to cover the gate electrodes, forming contact holes in the interlayer insulating film, and implanting impurities of the second general conductivity type into the channel layer through the contact holes.

11. The method of claim 7 or 8, wherein impurities of the second general conductivity type are injected into the channel layer so that a peak concentration thereof is located under the surface portion of the channel layer for the formation of the first and second body regions.
